(19) United States
(12) Patent Application Publication
(10) Pub. No.: US 2026/0013196 A1
(43) Pub. Date: Jan. 8, 2026

(54) SEMICONDUCTOR DEVICE AND FABRICATION METHOD THEREOF

(71) Applicant: Vanguard International Semiconductor Corporation, Hsinchu (TW)

(72) Inventors: Wen-Shan Lee, Hsinchu City (TW); Chung-Yeh Lee, Hsinchu County (TW); Fu-Hsin Chen, Hsinchu County (TW)

(73) Assignee: Vanguard International Semiconductor Corporation, Hsinchu (TW)

(21) Appl. No.: 18/764,175

(22) Filed: Jul. 4, 2024

(51) Int. Cl. H01L 29/40; H01L 29/423; H01L 29/66; H01L 29/78

(52) U.S. Cl. CPC H10D 64/117; H10D 30/0297; H10D 30/668; H10D 64/513

(57) ABSTRACT

A semiconductor device includes a trench disposed in a substrate. A first field plate and a second field plate are disposed in the trench. The second field plate is located below and laterally separated from the first field plate. A first dielectric layer and a second dielectric layer are disposed on a sidewall of the trench. The first dielectric layer surrounds an outer side surface of the first field plate and has a first thickness. The second dielectric layer surrounds a side surface and a bottom surface of the second field plate and has a second thickness greater than the first thickness. The first field plate is located directly above the second dielectric layer. A gate electrode is disposed on the substrate and physically connected to the first field plate.

### BACKGROUND OF THE INVENTION

### 1. Field of the Invention

The present disclosure relates generally to semiconductor technology, and more particularly to a semiconductor device including a vertical double-diffused metal oxide semiconductor structure and a fabrication method thereof.

### 2. Description of the Prior Art

Power transistors are usually used in power electronic systems as power switches, converters and other power components. Power transistors are typically operated under high voltage and high current. Metal-oxide-semiconductor field-effect-transistors (MOSFETs) are common power transistors, which include a horizontal structure such as laterally-diffused metal-oxide-semiconductor (LDMOS) field-effect-transistor (FET), and a vertical structure such as a planar gate MOSFET or a trench gate MOSFET. The planar gate MOSFET is, for example, a vertical double-diffused metal oxide semiconductor (VDMOS) transistor, which has the advantages of fast switching speed, high withstand voltage, etc. However, the conventional VDMOS transistors still cannot fully satisfy various requirements, such as simultaneously reducing the on-state resistance (Ron) and reducing various parasitic capacitances.

### SUMMARY OF THE INVENTION

In view of this, the present disclosure provides a semiconductor device and a fabrication method thereof. In the semiconductor device, a trench is disposed under a gate of a vertical double-diffused metal oxide semiconductor (VDMOS) structure. In addition, through the arrangement of field plates and dielectric layers in the trench, the on-state resistance (Ron), the gate-to-drain capacitance (Cgd) and other parasitic capacitances are reduced, thereby greatly improving switching loss and figure of merit (FOM) of the semiconductor device.

According to an embodiment of the present disclosure, a semiconductor device is provided and includes a substrate, a trench, a first field plate, a second field plate, a first dielectric layer, a second dielectric layer and a gate electrode. The trench is disposed in the substrate. The first field plate and the second field plate are disposed in the trench. The second field plate is located below and laterally separated from the first field plate. The first dielectric layer and the second dielectric layer are disposed on a sidewall of the trench. The first dielectric layer surrounds an outer side surface of the first field plate and has a first thickness. The second dielectric layer surrounds a side surface and a bottom surface of the second field plate and has a second thickness greater than the first thickness. The first field plate is located directly above the second dielectric layer. The gate electrode is disposed on the substrate and physically connected to the first field plate.

According to an embodiment of the present disclosure, a method of fabricating a semiconductor device is provided and includes the following steps. A substrate is provided and a trench is formed in the substrate. A first field plate is formed in the trench. A second field plate is formed in the trench, located below and laterally separated from the first field plate. A first dielectric layer is formed on a sidewall of the trench, surrounds an outer side surface of the first field plate and has a first thickness. A second dielectric layer is formed on the sidewall of the trench, surrounds a side surface and a bottom surface of the second field plate and has a second thickness greater than the first thickness. The first field plate is formed directly above the second dielectric layer. In addition, the gate electrode is formed on the substrate and physically connected to the first field plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to an embodiment of the present disclosure.

FIG. 2, FIG. 3, FIG. 4, FIG. 5, FIG. 6, FIG. 7, FIG. 8, FIG. 9 and FIG. 10 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device including a vertical double-diffused metal oxide semiconductor (VDMOS) structure and a fabrication method thereof. In some embodiments, an upper field plate and a lower field plate are disposed in a trench that is located directly below a gate electrode. The upper field plate is laterally spaced from the lower field plate. In addition, the upper field plate and the lower field plate are respectively surrounded by dielectric layers of different thicknesses. The thickness of a dielectric layer surrounding the upper field plate is much thinner than the thickness of another dielectric layer surrounding the lower field plate. Moreover, the upper field plate is in direct contact with and physically connected to the gate electrode. The lower field plate is electrically connected to a source electrode and grounded. The thinner dielectric layer located on the outer sidewall of the upper field plate is helpful for charge accumulation in a junction field-effect transistor (JFET) region, which is beneficial to reduce the on-state resistance (Ron). The thicker dielectric layer on the sidewall of the lower field plate can avoid electron accumulation, thereby reducing the gate-to-drain capacitance (Cgd) and further reducing the gate-to-drain charge (Qgd). Therefore, the switching loss and the figure of merit (FOM) of the semiconductor device are greatly improved. The FOM is the product of the on-state resistance (Ron) times the gate-to-drain charge (Qgd).

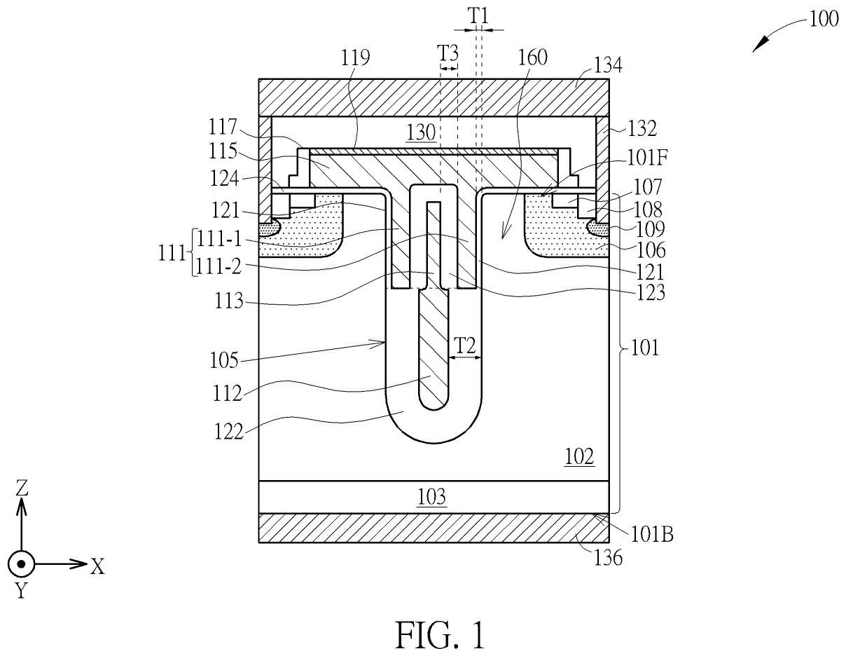

FIG. 1 is a schematic cross-sectional view of a semiconductor device 100 according to an embodiment of the present disclosure. The semiconductor device 100 includes a substrate 101 having a first surface 101F (for example, a front surface) opposite to a second surface 101B (for example, a back surface). Moreover, the substrate 101 includes a drain region 103 disposed at the second surface 110B. The drain region 103 has a first conductivity type, such as an n-type heavily doped (N⁺) region. The substrate 101 further includes an epitaxial layer 102 disposed on the drain region 103. The epitaxial layer 102 also has the first conductivity type, such as an n-type epitaxial layer. The doping concentration of the drain region 103 is much higher than that of the epitaxial layer 102. In some embodiments, the drain region 103 is, for example, an n-type heavily doped silicon (N⁺ Si) substrate or an n-type heavily doped silicon carbide (N⁺ SiC) substrate. The epitaxial layer 102 is, for example, an n-type lightly doped silicon (N⁻ Si) epitaxial layer or an n-type lightly doped silicon carbide (N⁻ SiC) epitaxial layer, but not limited thereto.

As shown in FIG. 1, the semiconductor device 100 includes a gate electrode 115 disposed on the first surface 101F of the substrate 101. A spacer 117 is disposed on the sidewall of the gate electrode 115. In one embodiment, a metal silicide layer 119 may be disposed on the top surface of the gate electrode 115 to reduce the intrinsic resistance of the gate electrode 115. The composition of the metal silicide layer 119 is, for example, cobalt silicide (CoSiₓ). In addition, a trench 105 is disposed in the epitaxial layer 102 of the substrate 101 and located directly below the gate electrode 115. A first field plate 111 is disposed in the trench 105. The first field plate 111 includes a first portion 111-1 and a second portion 111-2 laterally separated from each other. The first field plate 111 is in direct contact with and physically connected to the gate electrode 115. A second field plate 112 is also disposed in the trench 105, located below and laterally separated from the first field plate 111. The first field plate 111 and the second field plate 112 are not overlapped with each other in the vertical projection direction such as the Z-axis direction. In addition, a third field plate 113 is disposed in the trench 105, located directly above and physically connected to the second field plate 112. In a first direction perpendicular to the sidewall of the trench 105, such as the X-axis direction, the width of the third field plate 113 is smaller than the width of the second field plate 112. The third field plate 113 is also laterally separated from the first field plate 111. The first portion 111-1 and the second portion 111-2 of the first field plate 111 are located on two opposite sides of the third field plate 113, respectively. The first field plate 111 and the third field plate 113 are also not overlapped with each other in the vertical projection direction such as the Z-axis direction.

In addition, a first dielectric layer 121 is disposed on the sidewall of the trench 105, surrounds the outer side surface of the first field plate 111, and in direct contact with the outer side surface of the first portion 111-1 and the outer side surface of the second portion 111-2. In the first direction such as the X-axis direction, the first dielectric layer 121 has a first thickness T1. In some embodiments, the first thickness T1 is about 500 angstroms (Å) to about 600 Å, but not limited thereto. A second dielectric layer 122 is also disposed on the sidewall of the trench 105 and surrounds the side surface and the bottom surface of the second field plate 112. In the first direction such as the X-axis direction, the second dielectric layer 122 has a second thickness T2 greater than the first thickness T1. In some embodiments, the second thickness T2 is about 2000 Å to about 3000 Å, but not limited thereto. Moreover, the first field plate 111 is located directly above the second dielectric layer 122. In some embodiments, the second thickness T2 of the second dielectric layer 122 may be greater than the width of each of the first portion 111-1 and the second portion 111-2. Furthermore, a third dielectric layer 123 is disposed in the trench 105 and surrounds the side surface and the top surface of the third field plate 113. The third dielectric layer 123 is located between the first field plate 111 and the third field plate 113, and also located between the gate electrode 115 and the third field plate113. In the first direction such as the X-axis direction, the third dielectric layer 123 has a third thickness T3 that is greater than the first thickness T1 and may be less than or equal to the second thickness T2. In some embodiments, the third thickness T3 is approximately 2.5 times to 4 times the first thickness T1. In addition, a gate dielectric layer 124 is disposed between the gate electrode 115 and the substrate 101. The gate dielectric layer 124 is in direct contact with and physically connected to the first dielectric layer 121. The thickness of the gate dielectric layer 124 may be the same as the first thickness T1 of the first dielectric layer 121.

Still referring to FIG. 1, the semiconductor device 100 further includes a well region 106 disposed in the substrate 101 and at the first surface 101F. The well region 106 has a second conductivity type, such as a p-type well region. The well region 106 is located on two opposite sides of the trench 105. The well region 106 may be used as a body region (P-body), and the area between the well region 106 and the trench 105 is a junction field effect transistor (JFET) region 160. A source region 108 is disposed in the substrate 101, at the first surface 101F and located in the well region 106. The source region 108 has the first conductivity type, such as an n-type heavily doped (N⁺) region. The source region 108 is laterally separated from the gate electrodes 115. In one embodiment, the semiconductor device 100 may further include a lightly doped source region 107 disposed in the well region 106 and abutting to the side surface of the source region 108. The lightly doped source region 107 has the first conductivity type, such as an n-type lightly doped (N⁻) region. The lightly doped source region 107 is located directly below the spacer 117 that is disposed on the sidewall of the gate electrode 115. In the first direction such as the X-axis direction, the lightly doped source region 107 is located between the source region 108 and the gate electrode 115. The lightly doped source region 107 can reduce the peak electric field intensity near the source region 108, thereby avoiding or reducing the leakage current to improve the reliability of the semiconductor device 100.

In addition, an interlayer dielectric (ILD) layer 130 is disposed on the first surface 101F of the substrate 101 to cover the gate electrode 115, the spacer 117, the metal silicide layer 119 and the source region 108. A source electrode 134 is disposed above the first surface 101F of the substrate 101 and located on the ILD layer 130. The source electrode 134 is electrically connected to the source region 108 through a source contact 132. The source contact 132 passes through the ILD layer 130, the gate dielectric layer 124 and the source region 108, and further extends downward into the well region 106. A doped region 109 may be disposed directly below the bottom of the source contact 132 and in the well region 106. The doped region 109 has the second conductivity type, such as a p-type heavily doped (P⁺) region. The doped region 109 may be used as a bulk region and is electrically connected to the source electrode 134 through the source contact 132. Furthermore, a drain electrode 136 is disposed under the second surface 101B of the substrate 101 and in direct contact with the drain region 103.

The second field plate 112 and the third field plate 113 may be electrically connected to the source electrode 134 through an interconnect structure (not shown) disposed in the ILD layer 130 and several vias (not shown) passing through the third dielectric layer 123. The first field plate 111 is physically connected to the gate electrode 115, thereby electrically connecting to the gate electrode 115. According to some embodiments, the first thickness T1 of the first dielectric layer 121 surrounding the outer side surface of the first field plate 111 is much thinner than the second thickness T2 of the second dielectric layer 122 surrounding the side surface of the second field plate 112. In addition, the first field plate 111 is electrically connected to the gate electrode 115. As a result, the charge accumulation in the JFET region 160 is improved, thereby significantly reducing the on-state resistance (Ron) of the semiconductor device 100. Moreover, the second thickness T2 of the second dielectric layer 122 is much thicker than the first thickness T1 of the first dielectric layer 121, and the second field plate 112 is electrically connected to the source electrode 134 and grounded, which can avoid the accumulation of electrons. As a result, the gate-to-drain capacitance (Cgd) and the gate-to-drain charge (Qgd) are effectively reduced. Moreover, the gate-to-source capacitance (Cgs) is also reduced. Therefore, according to the embodiments of the present disclosure, the switching loss and the figure of merit (FOM) are significantly improved, and the electrical performances of the semiconductor device are further enhanced.

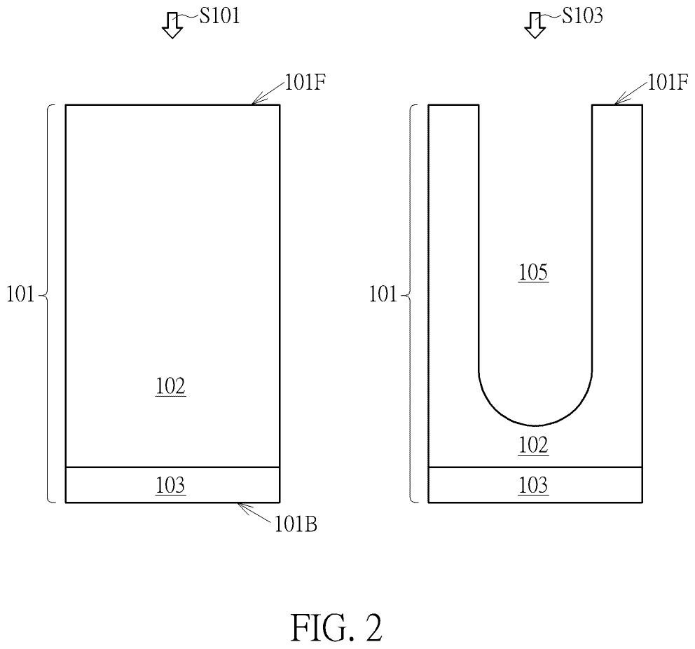

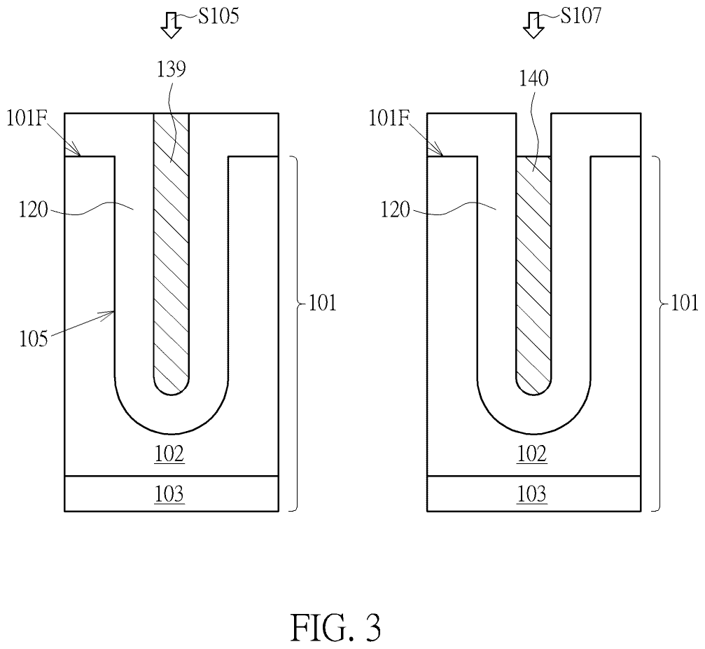

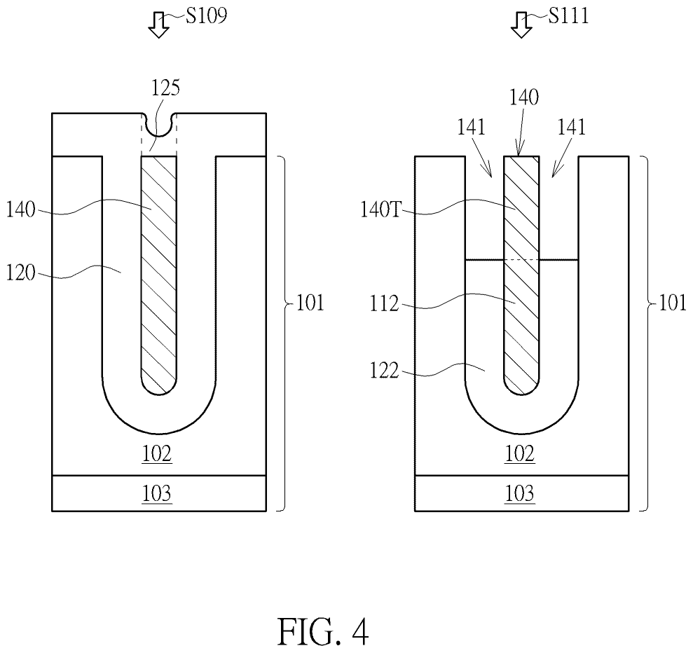

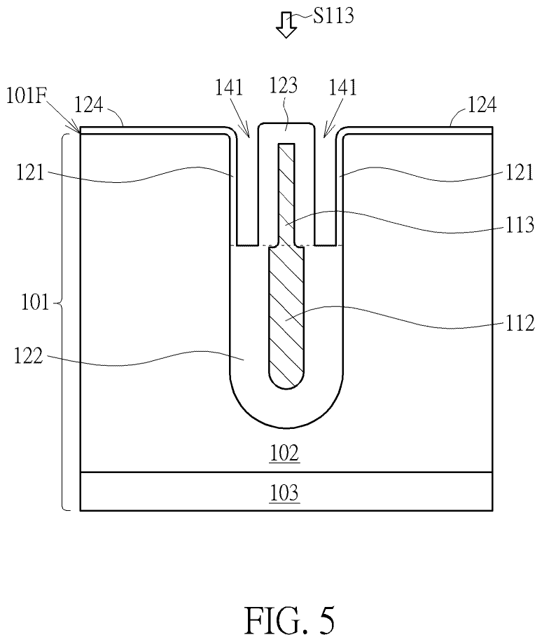

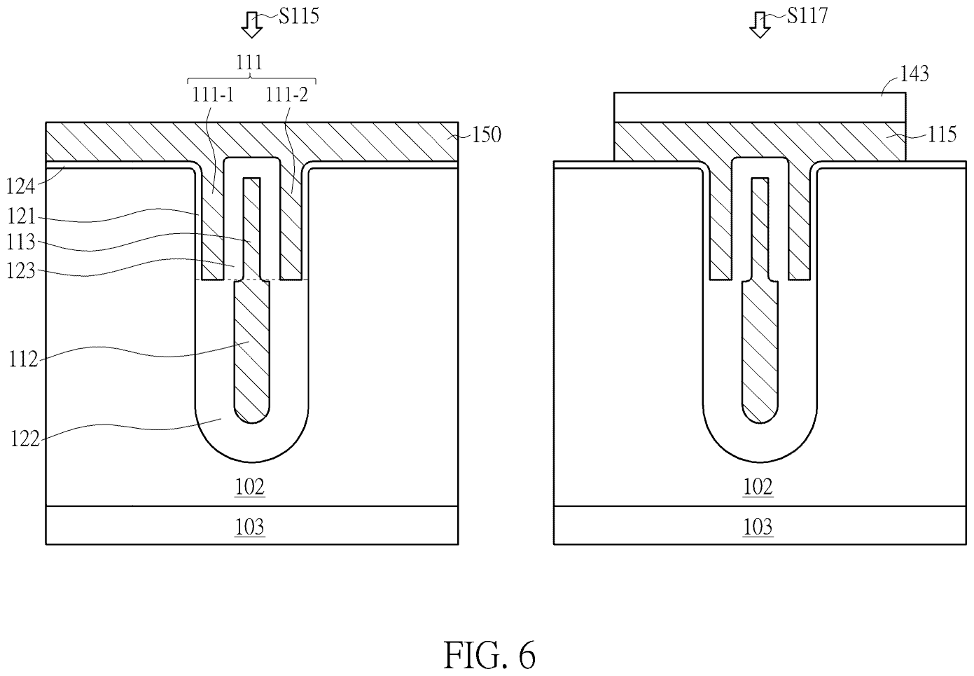

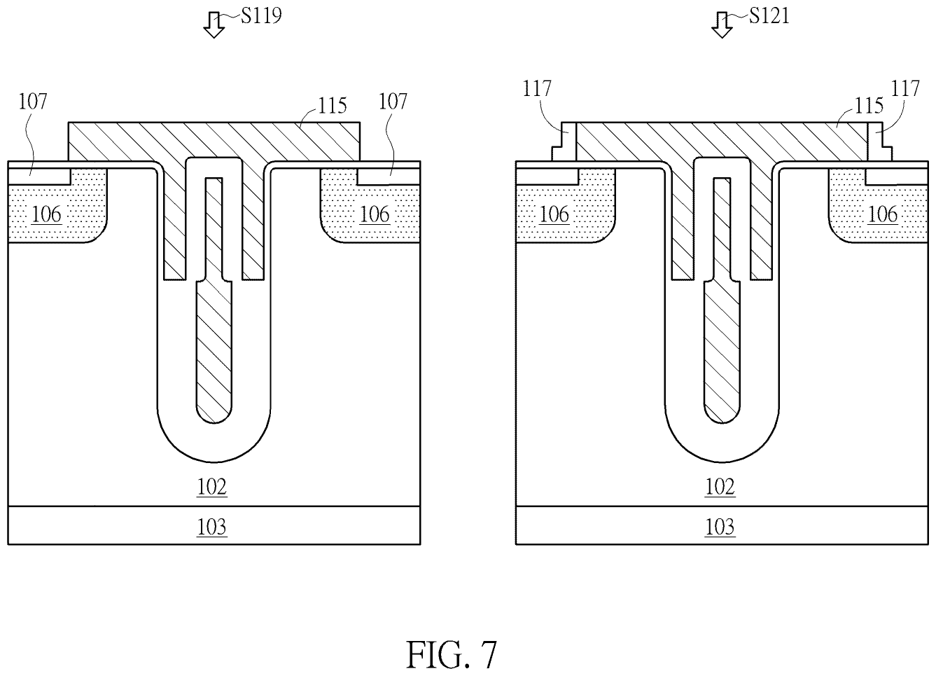

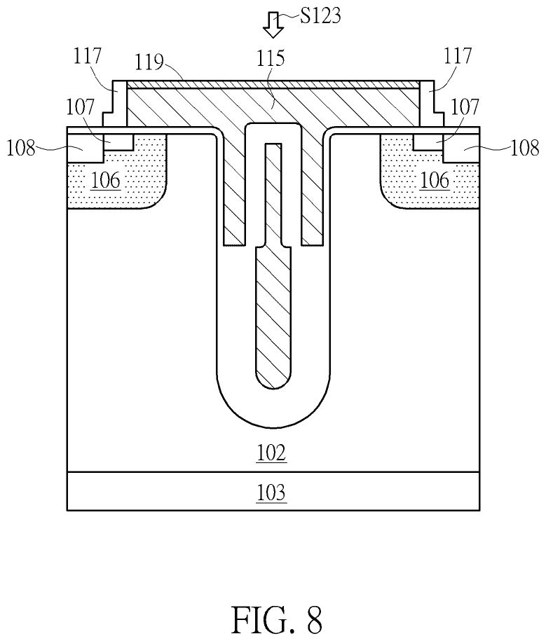

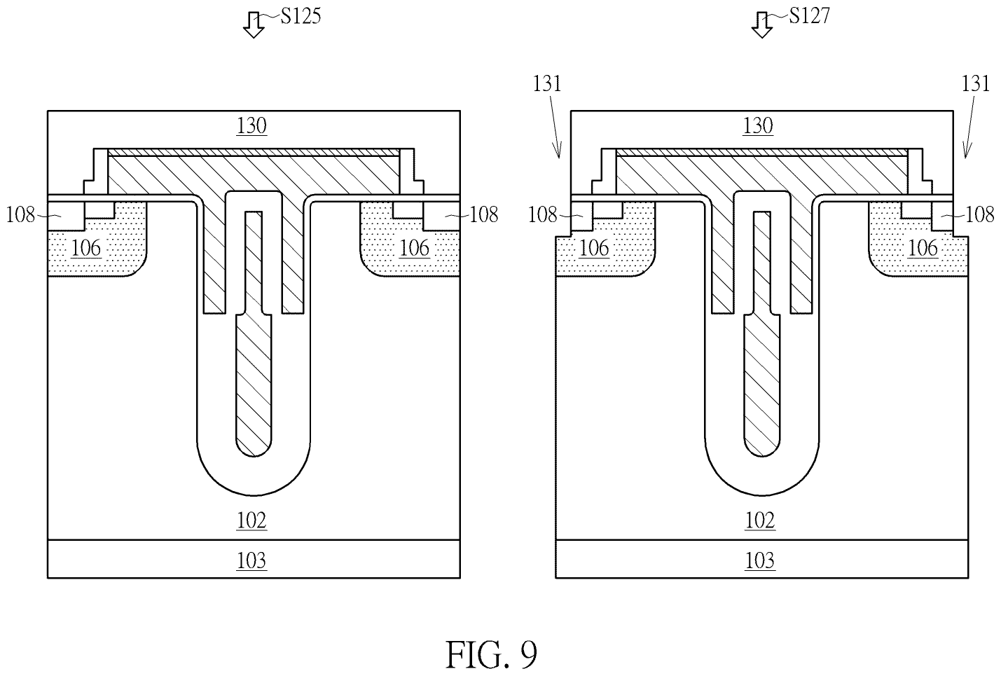

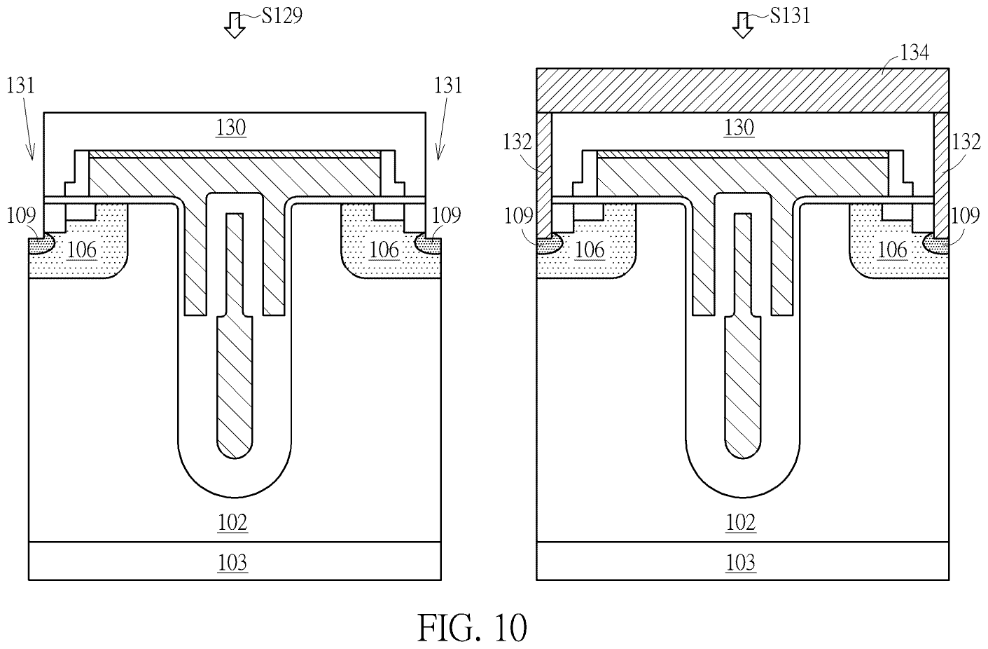

FIG. 2, FIG. 3, FIG. 4, FIG. 5, FIG. 6, FIG. 7, FIG. 8, FIG. 9 and FIG. 10 are schematic cross-sectional views of some stages of a method of fabricating a semiconductor device 100 according to an embodiment of the present disclosure. Referring to FIG. 2, in step S101, firstly, a substrate 101 is provided. The substrate 101 includes an epitaxial layer 102 grown on a drain region 103. In one embodiment, the drain region 103 is, for example, an n-type heavily doped silicon carbide substrate, and the epitaxial layer 102 is, for example, an n-type lightly doped silicon carbide epitaxial layer.

The substrate 101 has a first surface 101F opposite to a second surface 101B. Still referring to FIG. 2, in step S103, a trench 105 is formed in the epitaxial layer 102 of the substrate 101. In one embodiment, firstly, a hard mask layer is deposited on the first surface 101F of the substrate 101. Then, the hard mask layer is patterned by photolithography and etching processes to form a patterned hard mask having an opening. Next, the epitaxial layer 102 is etched by an etching process through the opening of the patterned hard mask to form the trench 105. Thereafter, the patterned hard mask is removed. Next, a sacrificial oxide layer (not shown) may be conformally formed in the trench 105, and then the sacrificial oxide layer is removed, thereby eliminating the defects caused by the etching process of forming the trench 105.

Next, referring to FIG. 3, in step S105, a dielectric material layer 120 is conformally formed in the trench 105 and on the first surface 101F of the substrate 101 by a thermal oxidation or a deposition process. The composition of the dielectric material layer 120 is, for example, silicon oxide. In one embodiment, the deposition process in the step S105 may be a sub-atmospheric undoped silicon glass (SAUSG) deposition using tetraethoxysilane (TEOS) and ozone (O₃) as reaction precursors. Then, a first semiconductor material layer 139 is deposited on the first surface 101F of the substrate 101 and fills up the trench 105 by a deposition process. During the deposition process, dopants with a conductivity type may be added to form a doped first semiconductor material layer. The composition of the doped first semiconductor material layer is, for example, doped polysilicon. Thereafter, a portion of the first semiconductor material layer 139 located on the top surface of the dielectric material layer 120 is removed by a chemical mechanical planarization (CMP) process, so that the top surface of a remaining portion of the first semiconductor material layer 139 is level with the top surface of the dielectric material layer 120. Still referring to FIG. 3, in step S107, a portion of the first semiconductor material layer 139 is removed by an etchback process to form an initial field plate 140. The top surface of the initial field plate 140 and the first surface 101F of the substrate 101 are substantially at same level in the height.

Then, referring to FIG. 4, in step S109, a dielectric material 125 is deposited on the initial field plate 140 by a deposition process. The surface of the dielectric material 125 is slightly recessed relative to the top surface of the dielectric material layer 120. The dielectric material 125 can protect the top surface of the initial field plate 140 during the subsequent etching process. In one embodiment, the dielectric material 125 is, for example, silicon oxide, and the deposition process in the step S109 may be a low-pressure chemical vapor deposition (LPCVD) process using tetraethoxysilane (TEOS) as a reaction precursor. Still referring to FIG. 4, in step S111, a portion of the dielectric material layer 120 is removed by a wet etching process, thereby forming a second dielectric layer 122 in the trench 105 and exposing an upper portion 140T of the initial field plate 140. A lower portion of the initial field plate 140 forms a second field plate 112, and the second dielectric layer 122 surrounds the side surface and the bottom surface of the second field plate 112. Moreover, openings 141 are formed in the trench 105 and located on two opposite sides of the upper portion 140T of the initial field plate 140.

Next, referring to FIG. 5, in step S113, the exposed surfaces of both the epitaxial layer 102 of the substrate 101 and the upper portion 140T of the initial field plate 140 are oxidized by a thermal oxidation process. The upper portion 140T of the initial field plate 140 is oxidized to form a third dielectric layer 123, and the remaining unoxidized portion of the upper portion 140T of the initial field plate 140 forms a third field plate 113. The width of the third field plate 113 is smaller than the width of the second field plate 112, and the third field plate 113 is physically connected to the second field plate 112. The third dielectric layer 113 surrounds the side surface and the top surface of the third field plate 113. In addition, the surface of the epitaxial layer 102 abutting the sidewall of the trench 105 and exposed by the openings 141 is also oxidized to form a first dielectric layer 121. The surface of the epitaxial layer 102 located at the first surface 101F of the substrate 101 is also oxidized to form a gate dielectric layer 124. The gate dielectric layer 124 is physically connected to the first dielectric layer 121. Moreover, the gate dielectric layer 124 and the first dielectric layer 121 may have the same first thickness T1.

In some embodiments, the composition of the epitaxial layer 102 is, for example, silicon carbide (SiC) or silicon (Si). The composition of the initial field plate 140 is, for example, polysilicon. The oxidation rate of polysilicon is approximately 3 times to 4 times that of silicon carbide (SiC). The oxidation rate of polysilicon is approximately 2.5 times to 3 times that of silicon (Si). As a result, the oxidation rate of the initial field plate 140 is higher than the oxidation rate of the epitaxial layer 102. Therefore, the third thickness T3 of the third dielectric layer 123 is greater than the first thickness T1 of the first dielectric layer 121. The third thickness T3 may be approximately 2.5 times to 4 times of the first thickness T1.

Referring to FIG. 6, in step S115, a second semiconductor material layer 150 is deposited on the first surface 101F of the substrate 101 and fills up the openings 141 in the trench 105 by a deposition process. During the deposition process, dopants with a conductivity type may be added to form a doped second semiconductor material layer. The composition of the doped second semiconductor material layer is, for example, doped polysilicon. A first field plate 111 is formed of the second semiconductor material layer 150 filling in the openings 141. The first field plate 111 includes a first portion 111-1 and a second portion 111-2 respectively located on two opposite sides of the third field plate 113. The third dielectric layer 123 is located between the first field plate 111 and the third field plate 113. The third field plate 113 is laterally separated from the first field plate 111. Next, a CMP process is performed on the top surface of the second semiconductor material layer 150. Still referring to FIG. 6, in step S117, firstly, a patterned photoresist 143 is formed on the second semiconductor material layer 150. Then, the second semiconductor material layer 150 is patterned by an etching process and using the patterned photoresist 143 as an etch mask to form a gate electrode 115.

Referring to FIG. 7, in step S119, the patterned photoresist 143 is removed, and an ion implantation process is performed on the first surface 101F of the substrate 101 to form a well region 106 in the epitaxial layer 102. The well region 106 has a second conductivity type, such as a p-type well region. The well region 106 is located on two opposite sides of the trench 105, and a portion of the well region 106 is laterally extended to be located under the gate electrode 115. Next, another ion implantation process is performed by using the gate electrode 115 as a mask to form a lightly doped source region 107 in the well region 106. The lightly doped source region 107 has the first conductivity type, such as an n-type lightly doped region. Still referring to FIG. 7, in step S121, a rapid thermal annealing (RTA) process is performed to activate the dopants in the well region 106 and the lightly doped source region 107. Thereafter, a spacer material layer is deposited on the sidewalls and the top surface of the gate electrode 115. Then, an anisotropic dry etching process is performed on the spacer material layer to remove a portion of the spacer material layer on the top surface of the gate electrode 115, thereby forming a spacer 117 on the sidewalls of the gate electrode 115.

Referring to FIG. 8, in step S123, an ion implantation process is performed by using the spacer 117 as a mask to form a source region 108 in the well region 106. The source region 108 has the first conductivity type, such as an n-type heavily doped region, and abuts the lightly doped source region 107. Afterwards, in one embodiment, a patterned resist-protection-oxide (RPO) layer is formed on the first surface 101F of the substrate 101 to cover the area other than the gate electrode 115 as a self-aligned silicide area block. Then, a metal layer, such as cobalt, is deposited on the top surface of the gate electrode 115, and a heat treatment is performed to cause the metal of the metal layer to react with the silicon in the gate electrode 115, thereby forming a metal silicide layer 119 on the top surface of the gate electrode 115. The composition of the metal silicide layer 119 is, for example, cobalt silicide (CoSiₓ). The metal silicide layer 119 is helpful to reduce the resistance of the gate electrode 115.

Then, referring to FIG. 9, in step S125, an interlayer dielectric (ILD) layer 130 is formed on the first surface 101F of the substrate 101 by a deposition process and a CMP process. The ILD layer 130 covers the gate electrode 115, the spacer 117, the metal silicide layer 119, the gate dielectric layer 124 and the source region 108. Still referring to FIG. 9, in step S127, a source contact hole 131 is formed by using a patterned photoresist and an etching process. The source contact hole 131 passes through the ILD layer 130, the gate dielectric layer 124 and the source region 108, and extends downward into the well region 106. The well region 106 is exposed through the bottom surface of the source contact hole 131, and the source region 108 is exposed through the sidewall of the source contact hole 131.

Next, referring to FIG. 10, in step S129, an ion implantation process is performed through the source contact hole 131 to form a doped region 109 in the well region 106 and directly below the source contact hole 131. The doped region 109 is used as a bulk region. The doped region 109 has the same conductivity type as the well region 106, and the doping concentration of the doped region 109 is higher than that of the well region 106. The doped region 109 is, for example, a p-type heavily doped (P⁺) region. Still referring to FIG. 10, in step S131, the source contact hole 131 is filled up with a conductive material, such as tungsten (W), copper (Cu) or other suitable metals to form a source contact 132. In addition, before filling the source contact hole 131 with the conductive material, a diffusion barrier layer may be conformally formed along the sidewalls and the bottom surface of the source contact hole 131 to prevent the metal of the source contact 132 from diffusing outward. The composition of the diffusion barrier layer is, for example, titanium nitride (TiN), tantalum (Ta), tantalum nitride (TaN), zirconium nitride (ZrN) or other suitable diffusion barrier materials. Then, a source electrode 134 is formed on the ILD layer 130 and the source contact 132 by deposition, photolithography and etching processes. The composition of the source electrode 134 is, for example, aluminum copper (AlCu) or other suitable metal materials. The source electrode 134 is electrically connected to the source region 108 and the doped region 109 through the source contact 132. In addition, the second field plate 112 and the third field plate 113 may be electrically connected to the source electrode 134 through other vias and wire layers. Next, a drain electrode 136 is formed under the second surface 101B of the substrate 101 by a deposition process and in direct contact with the drain region 103. Thereafter, the semiconductor device 100 of FIG. 1 is completed.

According to some embodiments, in the semiconductor device, the second dielectric layer with a thicker thickness and the first dielectric layer with a thinner thickness are formed in the trench located under the gate electrode. The first dielectric layer surrounds the outer side surface of the first field plate in the trench, and the first field plate is electrically connected to the gate electrode, thereby helping the charge accumulation in the JFET region to significantly reduce the on-state resistance (Ron) of the semiconductor device. In addition, the second dielectric layer surrounds the second field plate in the trench, and the second field plate is electrically connected to the source electrode and grounded, thereby preventing electron accumulation to effectively reduce the gate-to-drain capacitance (Cgd), and further reduce the gate-to-drain charge (Qgd). Therefore, according to the embodiments of the present disclosure, the switching loss and the figure of merit (FOM) are significantly improved, and the electrical performances of the semiconductor device are enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a trench, disposed in the substrate;
a first field plate, disposed in the trench;
a second field plate, disposed in the trench, located below the first field plate and laterally separated from the first field plate;
a first dielectric layer, disposed on a sidewall of the trench, surrounding an outer side surface of the first field plate, and having a first thickness;
a second dielectric layer, disposed on the sidewall of the trench, surrounding a side surface and a bottom surface of the second field plate, and having a second thickness greater than the first thickness, wherein the first field plate is located directly above the second the dielectric layer; and
a gate electrode, disposed on the substrate and physically connected to the first field plate.

2. The semiconductor device of claim 1, further comprising:
a third field plate, disposed in the trench, physically connected to the second field plate, and laterally separated from the first field plate; and
a third dielectric layer, disposed in the trench and located between the first field plate and the third field plate.

3. The semiconductor device of claim 2, wherein the third field plate has a third thickness greater than the first thickness and less than the second thickness.

4. The semiconductor device of claim 2, wherein the first field plate comprises a first portion and a second portion laterally separated from each other, and located on two opposite sides of the third field plate, respectively.

5. The semiconductor device of claim 2, wherein the third dielectric layer surrounds a side surface and a top surface of the third field plate, and the third dielectric layer is located between the gate electrode and the third field plate.

6. The semiconductor device of claim 2, wherein the third field plate is located directly above the second field plate, and a width of the third field plate is smaller than a width of the second field plate.

7. The semiconductor device of claim 1, wherein the first field plate is not overlapped with the second field plate in a vertical projection direction.

8. The semiconductor device of claim 1, further comprising:
a source region, disposed at a first surface of the substrate and laterally separated from the gate electrode;
a drain region, disposed at a second surface of the substrate;
a source electrode, disposed above the first surface of the substrate and electrically connected to the source region; and
a drain electrode, disposed under the second surface of the substrate and in direct contact with the drain region,
wherein the second field plate is electrically connected to the source electrode.

9. The semiconductor device of claim 1, further comprising a metal silicide layer disposed on a top surface of the gate electrode.

10. The semiconductor device of claim 1, further comprising a gate dielectric layer disposed between the gate electrode and the substrate, wherein the gate dielectric layer is physically connected to the first dielectric layer and has the first thickness.

11. A method of fabricating a semiconductor device, comprising:
providing a substrate;
forming a trench in the substrate;
forming a first field plate in the trench;
forming a second field plate in the trench, located below the first field plate and laterally separated from the first field plate;
forming a first dielectric layer on a sidewall of the trench, wherein the first dielectric layer surrounds an outer side surface of the first field plate and has a first thickness;
forming a second dielectric layer on the sidewall of the trench, wherein the second dielectric layer surrounds a side surface and a bottom surface of the second field plate and has a second thickness greater than the first thickness, and the first field plate is formed directly above the second dielectric layer; and
forming a gate electrode on the substrate and physically connected to the first field plate.

12. The method of claim 11, further comprising:
forming a third field plate in the trench, physically connected to the second field plate, and laterally separated from the first field plate; and
forming a third dielectric layer in the trench and located between the first field plate and the third field plate.

13. The method of claim 12, wherein forming the second field plate and the second dielectric layer comprises:
conformally forming a dielectric material layer in the trench;
depositing a first semiconductor material layer filling up the trench to form an initial field plate; and
removing a portion of the dielectric material layer to form the second dielectric layer and expose an upper portion of the initial field plate, wherein a lower portion of the initial field plate forms the second field plate and is surrounded by the second dielectric layer.

14. The method of claim 13, wherein forming the first dielectric layer, the third field plate and the third dielectric layer comprises:
performing an oxidation process on the substrate and the upper portion of the initial field plate,
wherein the upper portion of the initial field plate is oxidized to form the third dielectric layer, a remaining portion of the upper portion of the initial field plate forms the third field plate, a width of the third field plate is smaller than a width of the second field plate, the third dielectric layer surrounds the third field plate, and a portion of the substrate abutting the trench is oxidized to form the first dielectric layer.

15. The method of claim 14, wherein a surface of the substrate is oxidized to form a gate dielectric layer, the gate dielectric layer is physically connected to the first dielectric layer and has the first thickness.

16. The method of claim 14, wherein an oxidation rate of the initial field plate is higher than an oxidation rate of the substrate, and the third dielectric layer has a third thickness greater than the first thickness.

17. The method of claim 14, wherein forming the first field plate and the gate electrode comprises:
depositing a second semiconductor material layer on the substrate and filling up the trench, wherein the second semiconductor material layer in the trench forms the first field plate, and the first field plate comprises a first portion and a second portion located on two opposite sides of the third field plate, respectively; and
patterning the second semiconductor material layer on the substrate to form the gate electrode.

18. The method of claim 11, further comprising forming a metal silicide layer on a top surface of the gate electrode.

19. The method of claim 11, further comprising:
forming a source region at a first surface of the substrate, wherein the source region is laterally separated from the gate electrode;
forming a drain region at a second surface of the substrate;
forming a source electrode above the first surface of the substrate and electrically connected to the source region; and
forming a drain electrode under the second surface of the substrate and in direct contact with the drain region,
wherein the second field plate is electrically connected to the source electrode.

20. The method of claim 19, further comprising:
forming a well region at the first surface of the substrate, wherein the well region has a conductivity type opposite to that of the source region;
forming a lightly doped source region in the well region by using the gate electrode as a mask;
forming a spacer on a sidewall of the gate electrode;
forming the source region in the well region by using the spacer as a mask;
forming an interlayer dielectric layer to cover the gate electrode;
forming a source contact hole passing through the interlayer dielectric layer and the source region, and extending downward into the well region;
forming a doped region directly below the source contact hole, wherein the doped region has a conductivity type the same as the well region; and
filling the source contact hole with a conductive material to form a source contact electrically connected to the source electrode and the source region.
